(19) United States
(12) Patent Application Publication
(10) Pub. No.: US 2025/0298993 A1
(43) Pub. Date: Sep. 25, 2025

(54) SYSTEMS AND METHODS FOR ANALOG ELECTRONIC DESIGN AND ANALYSIS USING A MULTI-MODAL, MULTI-AGENT ARTIFICIAL INTELLIGENCE (AI) MODEL

(71) Applicant: Analog Devices, Inc., Wilmington, MA (US)

(72) Inventors: Wenjie Lu, Arlington, MA (US); Tao Yu, Needham, MA (US)

(21) Appl. No.: 19/087,027

(22) Filed: Mar. 21, 2025

Related U.S. Application Data
(60) Provisional application No. 63/568,924, filed on Mar. 22, 2024.

(51) Int. Cl. G06F 40/40; G06F 30/36

(52) U.S. Cl. CPC G06F 40/40; G06F 30/36

(57) ABSTRACT

Example implementations include a method, apparatus and computer-readable medium for automated analog electronic system design and analysis, comprising receiving a user query via a user interface. The implementations further include identifying, by a conversation agent of a machine learning model (MLM), at least one attribute of the user query. Additionally, the implementations further include selecting from a plurality of agents, by the conversation agent of the MLM, two or more agents that can collectively generate a response to the user query when executed in a specific sequence based on the at least one attribute of the user query. Additionally, the implementations further include prompting, by the conversation agent of the MLM, the two or more agents in the specific sequence to collectively generate the response. Additionally, the implementations further include outputting, by the conversation agent of the MLM, the response via the user interface.

### CROSS-REFERENCE TO RELATED APPLICATIONS

This application claims the benefit of U.S. Provisional Application No. 63/568,924, filed on Mar. 22, 2024, which is herein incorporated by reference.

### BACKGROUND

### Technical Field

The described aspects relate to machine learning, and more particularly to analog electronic design and analysis using a multi-modal, multi-agent artificial intelligence (AI) model.

### INTRODUCTION

Traditional electronic design methodologies often struggle with the complexity and intuition required for analog and mixed-signal integrated circuit development. Existing approaches are typically single-modality, focusing on narrow applications (such as device sizing or layout optimization), and lacking the capacity to generalize across the broad spectrum of design challenges. Moreover, the reliance on independent machine learning models and reinforcement learning agents restricts adaptability and fails to encapsulate the nuanced decision-making process that experienced engineers employ.

### SUMMARY

The present disclosure describes an artificial intelligence (AI) model for electronic system design and problem-solving, featuring a multi-modal, multi-agent architecture. The AI model includes a user-representative agent for logical task execution, a knowledge retrieval agent for context-specific information sourcing, a coding and tooling agent for software interaction, a simulation agent for circuit analysis, and a bench agent for hardware interfacing, with a focus on analog and mixed-signal IC domains. The multi-agent system is an extendable framework not limited to the agents mentioned above.

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

An example aspect includes a method for automated analog electronic system design and analysis, comprising receiving a user query via a user interface, wherein the user query includes at least one attribute indicative of a task in design of electronics, simulation of electronics, and/or analysis of electronics. The method further includes identifying, by a conversation agent of a machine learning model (MLM), the at least one attribute of the user query. Additionally, the method further includes selecting from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics. Additionally, the method further includes prompting, by the conversation agent of the MLM, the two or more agents in the specific sequence to collectively generate the response. Additionally, the method further includes outputting, by the conversation agent of the MLM, the response via the user interface.

Another example aspect includes an apparatus for automated analog electronic system design and analysis, comprising one or more memories and one or more processors coupled with one or more memories and configured to perform, individually or in any combination, the follow actions. The one or more processors are configured to receive a user query via a user interface, wherein the user query includes at least one attribute indicative of a task in design of electronics, simulation of electronics, and/or analysis of electronics. The one or more processors are further configured to identify, by a conversation agent of a machine learning model (MLM), the at least one attribute of the user query. Additionally, the one or more processors are further configured to select from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics. Additionally, the one or more processors are further configured to prompt, by the conversation agent of the MLM, the two or more agents in the specific sequence to collectively generate the response. Additionally, the one or more processors are further configured to output, by the conversation agent of the MLM, the response via the user interface.

Another example aspect includes an apparatus for automated analog electronic system design and analysis, comprising means for receiving a user query via a user interface, wherein the user query includes at least one attribute indicative of a task in design of electronics, simulation of electronics, and/or analysis of electronics. The apparatus further includes means for identifying the at least one attribute of the user query. Additionally, the apparatus further includes means for selecting from a plurality of agents two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics. Additionally, the apparatus further includes means for prompting the two or more agents in the specific sequence to collectively generate the response. Additionally, the apparatus further includes means for outputting the response via the user interface.

Another example aspect includes a computer-readable medium having instructions stored thereon for automated analog electronic system design and analysis, wherein the instructions are executable by one or more processors, individually or in any combination, to receive a user query via a user interface, wherein the user query includes at least one attribute indicative of a task in design of electronics, simulation of electronics, and/or analysis of electronics. The instructions are further executable to identify, by a conversation agent of a machine learning model (MLM), the at least one attribute of the user query. Additionally, the instructions are further executable to select from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics. Additionally, the instructions are further executable to prompt, by the conversation agent of the MLM, the two or more agents in the specific sequence to collectively generate the response. Additionally, the instructions are further executable to output, by the conversation agent of the MLM, the response via the user interface.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, wherein dashed lines may indicate optional elements, and in which:

FIG. 1 is a diagram of an example of an automated analog electronic design and analysis system including the different agents in the multi-agent AI model of the present disclosure.

FIG. 2 is a diagram of additional aspects of the automated analog electronic design and analysis system of FIG. 1, including the relationships between the conversation agent and all other portions of the AI model.

FIG. 3 is a message flow diagram of an interaction between the conversation agent and the circuit simulation agent.

FIG. 4 is a diagram of an example user interface of the AI model.

FIG. 5 is another diagram of an example user interface of the AI model.

FIG. 6 is a block diagram of an example of a computer device having components configured to perform a method for automated analog electronic system design and analysis;

FIG. 7 is a flowchart of an example of a method for automated analog electronic system design and analysis;

FIG. 8 is a flowchart of additional aspects of the method of FIG. 7;

FIG. 9 is a flowchart of additional aspects of the method of FIG. 7;

FIG. 10 is a flowchart of additional aspects of the method of FIG. 7; and

FIG. 11 is a flowchart of additional aspects of the method of FIG. 7.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

The present disclosure provides a comprehensive solution to the challenges of conventional electronic system design, particularly for analog and mixed-signal integrated circuits. It does so by integrating a multi-modal, multi-agent artificial intelligence (AI) framework that combines the capabilities of individual agents, powered by large language models (LLMs), each designed to handle specific facets of the electronic design process. This system not only streamlines the design and analysis of complex electronic systems but also imbues the process with a level of intuition and adaptability that closely mimics human expertise.

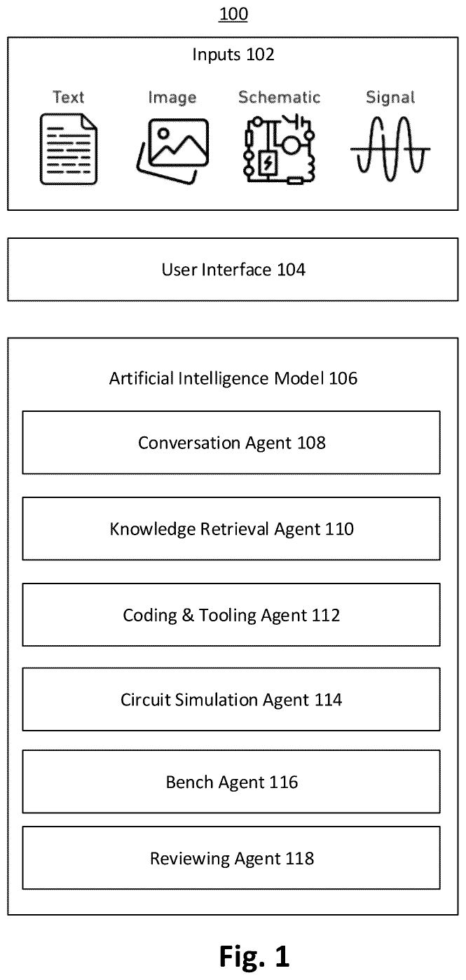

Referring to FIG. 1, which depicts a high-level diagram of an automated analog electronic design and analysis system 100 including the different agents in the multi-agent AI model 106 of the present disclosure, there are six types of agents shown. These agents include the following.

The Conversation Agent 108: This agent acts as the intermediary between the user and the AI model 106, interpreting inputs, and executing tasks in a logical sequence, akin to an engineer's thought process. The conversation agent 108 can also incorporate human feedback in the loop, such as by asking clarifying questions and requesting user actions via user interface 104. For example, the user may provide inputs 102 via user interface 104 to AI model 106. The conversation agent 108 receives inputs 102 and determines which agent(s) will handle the user query. In some aspects, inputs 102 includes text (e.g., a user query, a command, a description, etc.), images, schematics, signals, etc.

The Knowledge Retrieval Agent 110: Utilizing advanced indexing and search algorithms, agent 110 gathers relevant technical information from vast knowledge bases and the Internet, providing a context-aware foundation for decision-making.

The Coding and Tooling Agent 112: Agent 112 leverages a deep understanding of electronic systems to automate the generation and execution of code, interact with symbolic engines, and call upon various software tools necessary for design and analysis.

The Circuit Simulation Agent 114: Specialized in the creation and refinement of circuit simulations, agent 114 crafts netlists compatible with industry-standard simulators like LTspice or Cadence, analyzes simulation outcomes, and iteratively optimizes the design.

The Bench Agent 116: As the physical touchpoint of AI model 106, agent 116 is equipped to conduct real-world measurements and interact with electronic components and systems, providing empirical data to inform the design process. Agent 116 can also interact with the physical world, for example, by understanding an image of the bench setup that is provided by the conversation agent 108.

The Reviewing Agent 118: Agent 118 receives each of the outputs from agents 110-116 and verifies whether the outputs are accurate and/or meet the requirements/objectives set in the user query.

The multi-modal input capability allows the AI model 106 to process textual descriptions, images, electronic signals, and circuit schematics, ensuring comprehensive problem understanding. The agents collaborate through a dynamic communication process (in contrast to a pre-defined or static flow), ensuring that each step of the problem-solving process is informed by the insights and capabilities of the other agents. This dynamic communication and collaboration results in multiple agents collectively generating a response to a given user query.

The dynamic communication process among agents allows for a flexible and adaptive approach to problem-solving, where the sequence of agent interactions is not pre-defined but evolves based on real-time insights and feedback. This dynamic nature is achieved through continuous information exchange and iterative feedback loops among the agents, enabling them to adjust their actions and priorities as new data and results become available. For instance, in the design of a high-efficiency power amplifier, the initial sequence may involve the knowledge retrieval agent 110 gathering design principles, followed by the coding and tooling agent 112 generating a preliminary schematic. However, if the circuit simulation agent 114 identifies unexpected thermal issues during simulation, conversation agent 108 can communicate this insight back to the coding and tooling agent 112, prompting a redesign to address these thermal constraints. Simultaneously, the reviewing agent 118 may suggest alternative materials or configurations based on the simulation results, further influencing the sequence of actions. This dynamic collaboration ensures that each agent's capabilities are leveraged optimally, allowing the problem-solving process to adapt to emerging challenges and opportunities, ultimately leading to a more robust and efficient solution in providing automated design and analysis of an electronic device/system.

A principle of the AI model 106 lies in its multi-agent collaboration, where each agent's output informs the actions of the others, creating a feedback loop akin to a team of engineers working in concert. AI model 106 incorporates agents that can deal with circuit simulation and perform bench tasks, which are utilized for producing the design and analysis of real-world analog electronic systems.

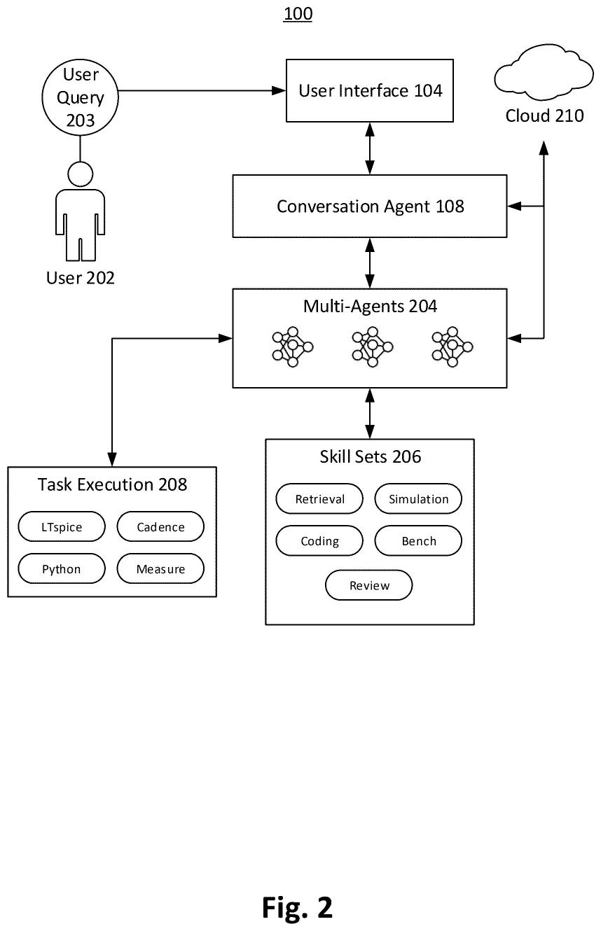

FIG. 2 is a diagram of additional aspects of the automated analog electronic design and analysis system 100 including the relationships between the conversation agent 108 and all other portions of the AI model 106. In FIG. 2, the user 202 initiates a task via a user query 203 via the user interface 104, which sets the objectives to be achieved. For example, a task may be to monitor and diagnose the condition of a device, or, it can be to answer an analog system design question, or it can be to design a new electronic device, or to revise the design of an existing electronic device based on new parameters.

In more specific examples, a user query may be “how is the device working? Summarize it's performance and report any issues . . . ” or “design and simulate LTM4700 with 12→1V with 100 A/us slew rate—set the compensation for the highest BW possible . . . .”

In response to receiving the user query 203, conversation agent 108 collaborates with a group of agents (i.e., multi-agents 204 comprised of agents 110-118). In some aspects, conversation agent 108 and multi-agents 204 are hosted on the cloud 210 (e.g. Azure AI, Vertex AI, AWS).

Agent 108 decides which agent to talk to and forwards the task to the selected one or more agents. In the multi-agent system, each agent is programmed with specific skill sets 206. For example, the knowledge retrieval agent 110 is configured to retrieve context knowledge from technical documents, and the circuit simulation agent 114 is configured to set up simulations that can be run in LTspice or Cadence, which are part of the task execution environment 208. It should be noted that the task execution environment 208 includes any software associated with the design and analysis (both software and hardware) of electronics.

In the context of the automated analog electronic design and analysis system described, historical knowledge can be leveraged by the knowledge retrieval agent 110 to enhance decision-making and design accuracy. For instance, when a user queries AI model 106 to design a specific type of amplifier circuit, the knowledge retrieval agent 110 may access a repository of technical documents and past simulation data. This includes querying historical records of engineers' design choices, challenges faced, and solutions implemented in similar projects. Additionally, the agent 110 may retrieve prior simulation results that highlight the performance characteristics and optimization strategies of analogous circuits. By integrating this historical knowledge, AI model 106 can provide a more informed and context-aware foundation for the current design task, suggesting proven methodologies and potential pitfalls to avoid, thereby streamlining the design process and improving the likelihood of success.

Each selected agent will try to make progress on the task by using its skill. For example, the circuit simulation agent 114 may generate circuit netlists for a design question. The conversation agent 108 may incorporate that response into an output for user review and may further decide if additional actions are necessary.

If an action is needed (e.g., run the circuit netlists in LTspice), agent 108 will execute the action by sending commands in the task execution environment 208. The execution results will be returned to the conversation agent 108.

Based on the execution results, conversation agent 108 identifies the next agent that will work on the task. This process will keep running until agent 108 determines that the task is completed and the user query can be resolved.

In some aspects, at each round of conversation, the user 202 may provide feedback to the conversation agent 108 (human-in-the-loop) based on intermediate results generated by multi-agents 204.

In general, the conversation agent 108 acts as the central coordinator, determining which specialized agents should handle a user query 203 based on the nature and requirements of the task. When the user 202 initiates a task, agent 108 first interprets the input to understand the objectives and context, and then decides which agents are best suited to address the query by analyzing the type of information or action required. For instance, if the task is to monitor and diagnose the condition of a device, agent 108 may first engage the knowledge retrieval agent 110 to gather relevant technical information and context. Following this, it could involve the bench agent 116 to conduct real-world measurements and provide empirical data. Finally, reviewing agent 118 may verify the accuracy and relevance of the outputs from the other agents to ensure the task objectives are met.

In another scenario, if the task is to answer an analog system design question, agent 108 may first consult the knowledge retrieval agent 110 to gather foundational information. It could then engage the coding and tooling agent 112 to generate and execute necessary code or simulations. The circuit simulation agent 114 may be involved next to create and refine circuit simulations, providing insights into the design's performance. Throughout this process, agent 108 ensures that each agent's output is logically sequenced and aligned with the task's objectives, ultimately leading to a comprehensive and accurate response. The reviewing agent 118 would again play a role in verifying the final outputs before presenting them to the user.

In some aspects, conversation agent 108 determines which agent to send commands to by leveraging a combination of predefined rules, contextual analysis, and/or machine learning algorithms. It begins by parsing the user query to identify key elements such as the type of task, required outputs, and any specific constraints or objectives. Using this information, agent 108 applies a set of decision-making protocols that map different types of queries to the capabilities of each specialized agent. For instance, if the query involves technical information retrieval, the agent recognizes that the knowledge retrieval agent 110 is equipped to handle such tasks. Additionally, the conversation agent 108 may utilize historical data and feedback loops to refine its decision-making process, learning from past interactions to improve accuracy and efficiency.

In some aspects, agent 108 also considers the sequence of operations needed to achieve the task objectives, ensuring that each agent's output logically contributes to the next step in the process. This dynamic and adaptive approach allows the conversation agent 108 to effectively coordinate complex tasks across multiple agents.

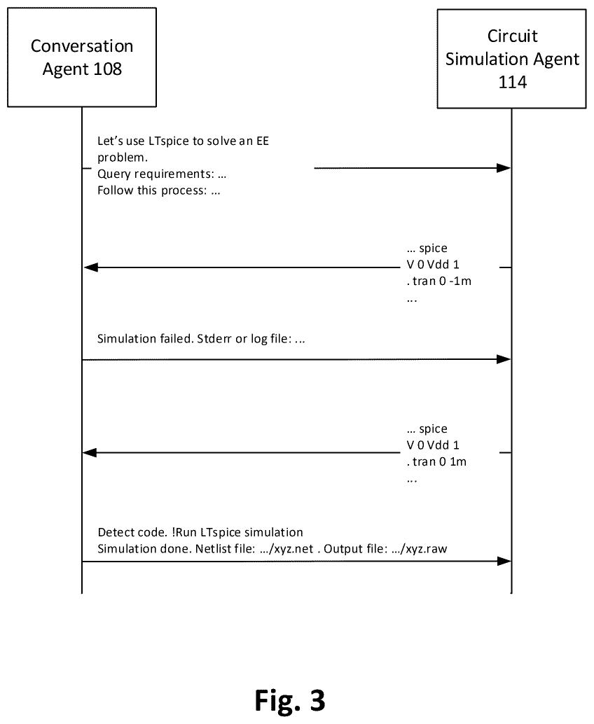

FIG. 3 is a diagram of an interaction between the conversation agent 108 and the circuit simulation agent 114. For example, conversation agent 108 commands agent 114, stating “Let's use LTspice to solve an EE problem. Query requirements: . . . Follow this process: . . . ” and circuit simulation agent 114 responds with:

“. . . spice
V 0 Vdd 1
. tran 0 −1m
...”

Subsequent to entering this as an input in LTspice, conversation agent 108 determines that the simulation has failed. Based on the failed simulation, conversation agent 108 determines that agent 114 needs to be commanded once again. Accordingly, conversation agent 108 commands agent 114, stating “Simulation failed. Stderr or log file: . . . ” Based on the provided log file indicating the error, agent 114 generates a modified output:

“. . . spice
V 0 Vdd 1
. tran 0 1m
...”

When conversation agent 108 enters this as an input in LTspice, the result is successful and agent 108 passes the results from LTspice to agent 114.

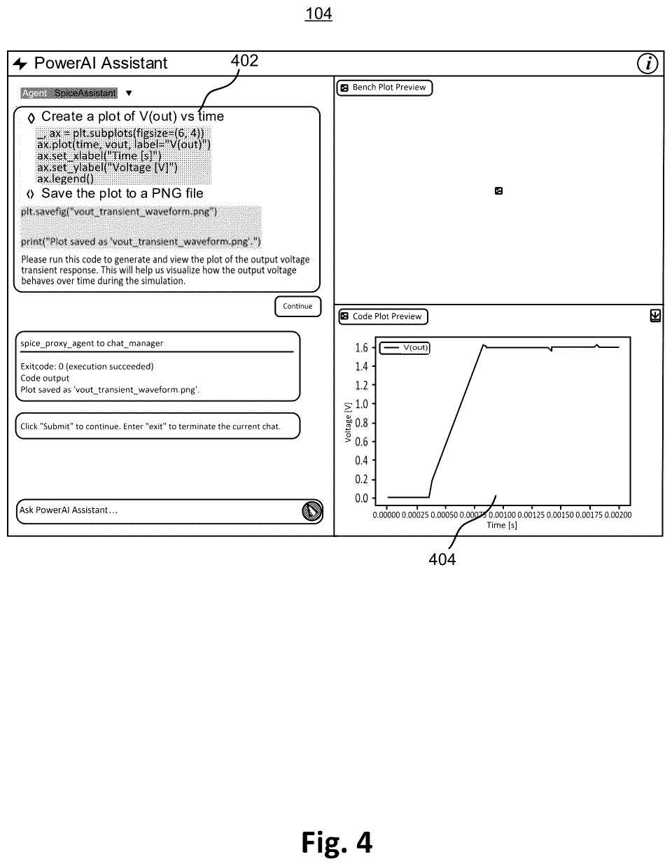

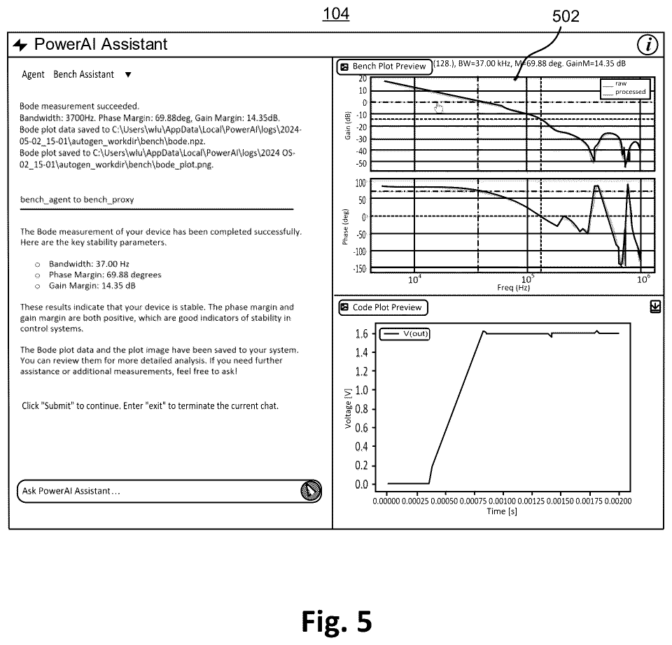

FIG. 4 is a diagram of an example user interface 104 of the AI model. In this example, the user 202 provides code 402 to conversation agent 108 and states in a user query 203 “please run this code to generate and view the plot of the output voltage transient response. This will help us visualize how the output voltage behaves over time during the simulation.” Agent 108 may pass this command to agent 114, which outputs the plot 404 to the user interface 104 and provides a confirmation message. It should be noted that no bench plot preview is generated in FIG. 4 because it has not been requested (it will be requested in FIG. 5).

FIG. 5 is another diagram of an example user interface 104 of the AI model. In this example, the bench agent 116 is tasked by conversation agent 108 to perform a bode measurement of the device simulated in FIG. 4, which results in the output of graph 502.

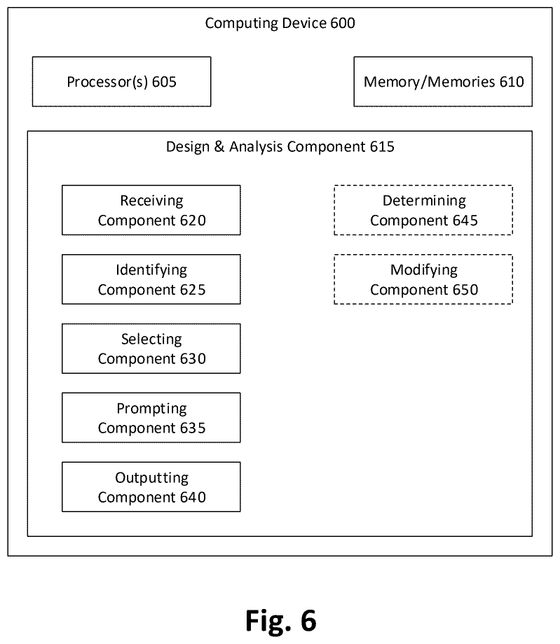

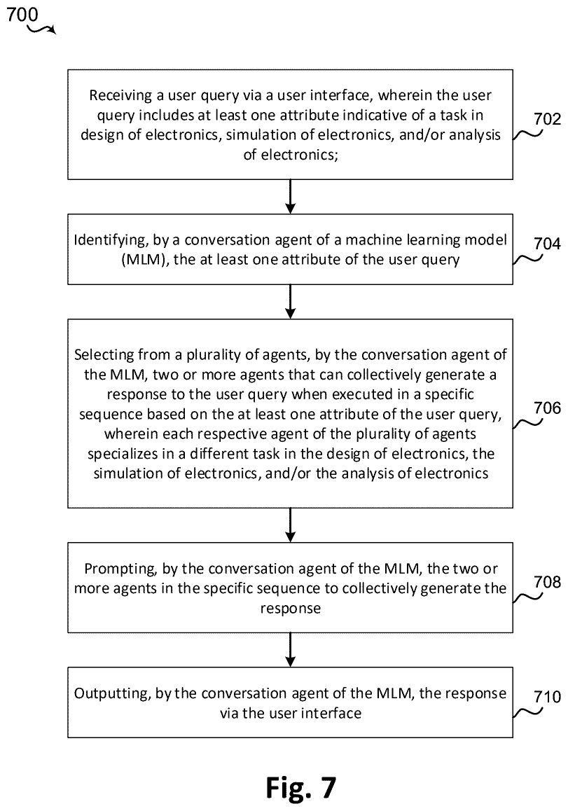

Referring to FIG. 6 and FIG. 7, in operation, computing device 600 may perform a method 700 for automated analog electronic system design and analysis, such as via execution of design and analysis component 615 by one or more processors 605 configured, individually or in any combination, to execute instructions to perform the following actions, and/or configured to communicate with one or more memories 610 to obtain the instructions.

At block 702, the method 700 includes receiving a user query via a user interface, wherein the user query includes at least one attribute indicative of a task in design of electronics, simulation of electronics, and/or analysis of electronics. For example, in an aspect, computing device 600, one or more processors 605, one or more memories 610, design and analysis component 615, and/or receiving component 620 may be configured to or may comprise means for receiving a user query via a user interface 104, wherein the user query includes at least one attribute indicative of a task in design of electronics, simulation of electronics, and/or analysis of electronics.

For example, the user query may be “design a low-pass filter with a cutoff frequency of 1 kHz for an audio application. Provide the circuit schematic, simulate its performance, and suggest any improvements for optimal performance.”

At block 704, the method 700 includes identifying, by a conversation agent of a machine learning model (MLM), the at least one attribute of the user query. For example, in an aspect, computing device 600, one or more processors 605, one or more memories 610, design and analysis component 615, and/or identifying component 625 may be configured to or may comprise means for identifying, by a conversation agent of a machine learning model (MLM), the at least one attribute of the user query. In an alternative or additional aspect, the MLM is a large language model.

For example, the identifying at block 704 may include parsing the user query to identify key attributes such as the type of task, specific objectives, and constraints. This involves utilizing natural language processing algorithms to interpret the text input, extracting relevant information that indicates whether the task pertains to the design, simulation, or analysis of electronics. The output of this process is a structured representation of the query, which the conversation agent 108 uses to determine the appropriate sequence of actions and the specialized agents to engage, such as the knowledge retrieval agent 110 for gathering technical information, the coding and tooling agent 112 for code generation, or the circuit simulation agent 114 for simulation tasks.

Referring to the previous query, agent 108 may determine that the user is requesting the design and analysis of an electronic component (a low-pass filter), specifying the desired cutoff frequency and application context. The conversation agent 108 would interpret this query to determine the necessary steps and engage the appropriate agents, such as the knowledge retrieval agent 110 for gathering design principles, the coding and tooling agent 112 for generating the circuit schematic, and the circuit simulation agent 114 for simulating and analyzing the filter's performance.

In some aspects, the identifying at block 704 may include processing the structured representation of the user query determined after parsing. This may involve applying decision trees to categorize the query attributes based on predefined criteria. The input to this process is the parsed data from the user query, which includes elements like task type, objectives, and constraints. The conversation agent uses these algorithms to match the query attributes with the capabilities of the available agents, determining which agents are best suited to handle the task.

In some aspects, the output may be a prioritized list of attributes and corresponding agents, guiding the conversation agent in orchestrating the task execution sequence effectively. In the context of the user query “design a low-pass filter with a cutoff frequency of 1 kHz for an audio application. Provide the circuit schematic, simulate its performance, and suggest any improvements for optimal performance,” the prioritization process involves a systematic evaluation of task attributes and their corresponding agents, ensuring an efficient execution sequence. The conversation agent 108 begins by parsing the query to identify key attributes, such as “design,” “simulate,” and “improve.” These attributes are then mapped to specialized agents based on their functional capabilities. The prioritization is mathematically modeled using a decision matrix, where each attribute is assigned a weight based on its dependency and criticality in the task sequence. For instance, the design attribute, linked to the knowledge retrieval agent 110, is prioritized first as it provides the foundational transfer function, logically needed for subsequent steps. The coding and tooling agent 112 follows, translating these mathematical models into a circuit schematic. The circuit simulation agent 114 is next, employing numerical methods to analyze the filter's frequency response, which is needed for performance validation. Finally, the reviewing agent 118 is utilized to apply optimization algorithms, such as gradient descent, to refine the design parameters. This structured prioritization ensures that each agent's output is optimally sequenced, leveraging mathematical dependencies and logical flow to achieve the task objectives efficiently.

At block 706, the method 700 includes selecting from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics. For example, in an aspect, computing device 600, one or more processors 605, one or more memories 610, design and analysis component 615, and/or selecting component 630 may be configured to or may comprise means for selecting from a plurality of agents (multi-agents 204), by conversation agent 108 of the MLM (e.g., AI model 106), two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics.

For example, the selecting at block 706 may include analyzing the structured representation of the user query obtained from previous blocks, focusing on the identified attributes and their associated tasks. The conversation agent 108 employs a selection algorithm, such as a weighted scoring system or a decision tree, to evaluate the suitability of each agent based on their specialization and the requirements of the task. The input to this process includes the parsed query attributes, the capabilities of each agent, and any historical performance data that may inform the selection. The algorithm assigns scores to each agent, reflecting their ability to contribute effectively to the task, and prioritizes them based on these scores. The output is a sequence of selected agents, each specializing in different aspects of electronics design, simulation, or analysis, arranged in an order that optimizes the task execution. For instance, in the query about designing a low-pass filter, the knowledge retrieval agent 110 may be selected first to gather design principles, followed by the coding and tooling agent 112 for schematic generation, the circuit simulation agent 114 for performance analysis, and finally the reviewing agent 118 for validation and improvement suggestions. This selection process ensures that the agents collectively generate a comprehensive and accurate response to the user query.

At block 708, the method 700 includes prompting, by the conversation agent of the MLM, the two or more agents in the specific sequence to collectively generate the response. For example, in an aspect, computing device 600, one or more processors 605, one or more memories 610, design and analysis component 615, and/or prompting component 635 may be configured to or may comprise means for prompting, by the conversation agent of the MLM, the two or more agents in the specific sequence to collectively generate the response.

For example, the prompting at block 708 may include initiating communication between the conversation agent 108 and the selected agents in the predetermined sequence. The conversation agent sends structured commands or requests to each agent, detailing the specific tasks they need to perform based on the user query attributes. The input to this process includes the sequence of selected agents and the detailed task requirements derived from the user query. The conversation agent applies a coordination algorithm, such as a task scheduling protocol, to manage the timing and dependencies between agents, ensuring that each agent receives the necessary inputs from preceding agents before executing its task.

For instance, in the query about designing a low-pass filter, the conversation agent first prompts the knowledge retrieval agent 110 to gather relevant design principles and technical information. Once this information is obtained, the conversation agent then prompts the coding and tooling agent 112 to generate the circuit schematic using the gathered data. Subsequently, the circuit simulation agent 114 is prompted to simulate the filter's performance, analyzing the frequency response and transient behavior. Finally, the reviewing agent 118 is prompted to validate the outputs and suggest improvements, ensuring the design meets the specified performance criteria.

The output of this prompting process is a coordinated execution of tasks by the agents, resulting in a comprehensive and accurate response to the user query. This approach ensures that each agent's contribution is integrated effectively, leveraging their specialized capabilities to achieve the task objectives efficiently.

At block 710, the method 700 includes outputting, by the conversation agent of the MLM, the response via the user interface. For example, in an aspect, computing device 600, one or more processors 605, one or more memories 610, design and analysis component 615, and/or outputting component 640 may be configured to or may comprise means for outputting, by the conversation agent of the MLM, the response via the user interface.

For example, the outputting at block 710 may include compiling the results generated by the various agents into a cohesive and user-friendly format. The conversation agent 108 aggregates the outputs from each agent, ensuring that the information is logically organized and clearly presented. The input to this process includes the final outputs from the selected agents, such as design schematics, simulation results, and improvement suggestions. The conversation agent applies formatting algorithms to structure the data, possibly converting technical outputs into visual representations like graphs or diagrams for easier interpretation.

For instance, in the query about designing a low-pass filter, the conversation agent would compile the circuit schematic generated by the coding and tooling agent 112, the simulation results from the circuit simulation agent 114, and the improvement suggestions from the reviewing agent 118. These elements are integrated into a comprehensive report or interactive interface that allows the user to explore the design details, view performance metrics, and understand the suggested optimizations.

The output of this process is a well-organized response delivered via the user interface, providing the user with a clear and actionable understanding of the task's outcomes. This ensures that the user can easily interpret the results and make informed decisions based on the comprehensive analysis provided by the agents.

In an alternative or additional aspect, the plurality of agents include one or more of: a knowledge retrieval agent 110 that collects information from databases, a coding agent 112 that writes code in one or more programming languages, a circuit simulation agent 114 that designs and simulates circuits, a bench agent 116 that interfaces with instruments to perform the analysis of electronics, and a reviewing agent 118 that evaluates responses of all other agents in the plurality of agents and identifies errors.

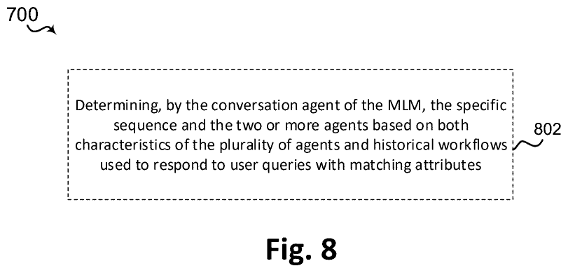

Referring to FIG. 8, in an alternative or additional aspect, at block 802, the method 700 may further include determining, by the conversation agent of the MLM, the specific sequence and the two or more agents based on both characteristics of the plurality of agents and historical workflows used to respond to user queries with matching attributes. For example, in an aspect, computing device 600, one or more processors 605, one or more memories 610, design and analysis component 615, and/or determining component 645 may be configured to or may comprise means for determining, by the conversation agent of the MLM, the specific sequence and the two or more agents based on both characteristics of the plurality of agents and historical workflows used to respond to user queries with matching attributes.

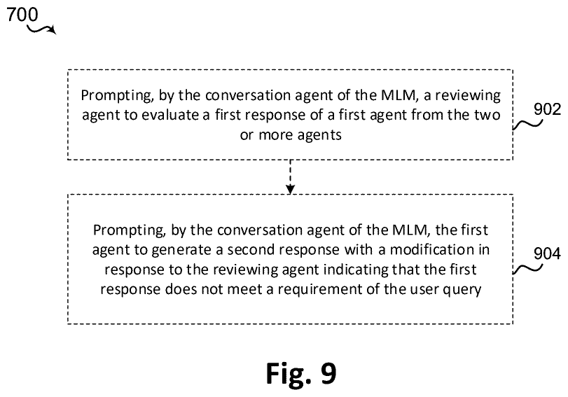

Referring to FIG. 9, in an alternative or additional aspect, at block 902, the method 700 may further include prompting, by the conversation agent of the MLM, a reviewing agent to evaluate a first response of a first agent from the two or more agents. For example, in an aspect, computing device 600, one or more processors 605, one or more memories 610, design and analysis component 615, and/or prompting component 635 may be configured to or may comprise means for prompting, by the conversation agent of the MLM, a reviewing agent to evaluate a first response of a first agent from the two or more agents.

In this optional aspect, at block 904, the method 700 may further include prompting, by the conversation agent of the MLM, the first agent to generate a second response with a modification in response to the reviewing agent indicating that the first response does not meet a requirement of the user query. For example, in an aspect, computing device 600, one or more processors 605, one or more memories 610, design and analysis component 615, and/or prompting component 635 may be configured to or may comprise means for prompting, by the conversation agent of the MLM, the first agent to generate a second response with a modification in response to the reviewing agent indicating that the first response does not meet a requirement of the user query.

For example, the prompting at block 904 may include initiating a feedback loop between the conversation agent 108 and the first agent, based on the evaluation provided by the reviewing agent 118. The conversation agent receives the assessment from the reviewing agent, which includes specific details on how the first response fails to meet the user query requirements. This input consists of structured feedback, highlighting discrepancies or areas needing improvement, such as incorrect data, insufficient analysis, or unmet performance criteria.

The conversation agent then applies a modification algorithm, which could involve rule-based adjustments to determine the necessary changes to the first agent's response. This algorithm analyzes the feedback to identify actionable modifications, such as recalibrating parameters, refining calculations, or enhancing data accuracy.

The output of this process is a set of revised instructions or parameters sent to the first agent, prompting it to generate a second response that addresses the identified shortcomings. This iterative approach ensures that the final output aligns with the user query's requirements, leveraging the reviewing agent's expertise to enhance the quality and accuracy of the response.

In an alternative or additional aspect, each respective agent of the plurality of agents has a corresponding reviewing agent configured to evaluate intermediate responses generated by the respective agent.

In an alternative or additional aspect, the two or more agents includes a first agent and a second agent, wherein the first agent is executed after the second agent in the specific sequence, and wherein an intermediate response of the second agent is provided to the first agent to generate the response outputted on the user interface.

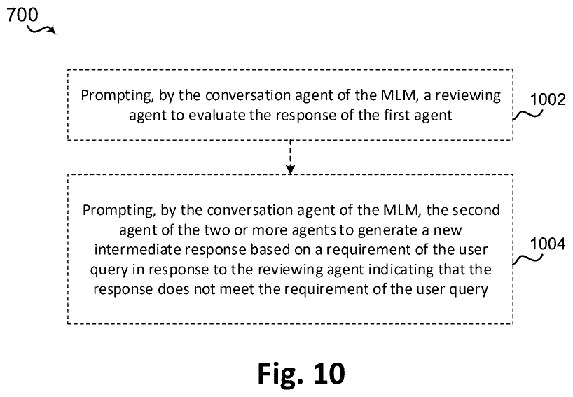

Referring to FIG. 10, in an alternative or additional aspect, at block 1002, the method 700 may further include prompting, by the conversation agent of the MLM, a reviewing agent to evaluate the response of the first agent. For example, in an aspect, computing device 600, one or more processors 605, one or more memories 610, design and analysis component 615, and/or prompting component 635 may be configured to or may comprise means for prompting, by the conversation agent of the MLM, a reviewing agent to evaluate the response of the first agent.

In this optional aspect, at block 1004, the method 700 may further include prompting, by the conversation agent of the MLM, the second agent of the two or more agents to generate a new intermediate response based on a requirement of the user query in response to the reviewing agent indicating that the response does not meet the requirement of the user query. For example, in an aspect, computing device 600, one or more processors 605, one or more memories 610, design and analysis component 615, and/or prompting component 635 may be configured to or may comprise means for prompting, by the conversation agent of the MLM, the second agent of the two or more agents to generate a new intermediate response based on a requirement of the user query in response to the reviewing agent indicating that the response does not meet the requirement of the user query.

For example, the prompting at block 1004 may include initiating a corrective feedback loop where the conversation agent 108 coordinates with the second agent to refine its intermediate response. This process begins with the reviewing agent 118 evaluating the response of the first agent and identifying any deficiencies or unmet requirements in relation to the user query. The input to this process includes detailed feedback from the reviewing agent, specifying the aspects of the response that need adjustment, such as inaccuracies, incomplete data, or failure to meet specified criteria.

The conversation agent then applies a feedback-driven modification algorithm, which could involve heuristic methods to determine the necessary changes to the intermediate response generated by the second agent. This algorithm processes the feedback to identify specific areas for improvement, such as recalibrating models, enhancing data processing, or adjusting parameters to better align with the user query's requirements.

The output of this process is a set of revised instructions or parameters sent to the second agent, prompting the second agent to generate a new intermediate response that addresses the identified issues. This iterative refinement ensures that the intermediate response is optimized before being used by the first agent to generate the final output, thereby enhancing the overall quality and accuracy of the response presented to the user.

In an alternative or additional aspect, the specific sequence comprises executing at least one of the two or more agents multiple times in different parts of the specific sequence. Consider a user query focused on designing a high-precision digital-to-analog converter (DAC) with stringent specifications for linearity, resolution, and power consumption. The conversation agent 108 orchestrates the task by engaging various agents in a specific sequence, with some agents being executed multiple times to ensure the design meets all criteria.

Initially, the knowledge retrieval agent 110 is executed to gather comprehensive technical information and design principles relevant to DACs. This foundational knowledge informs the coding and tooling agent 112, which is executed to generate an initial circuit schematic. The circuit simulation agent 114 follows, simulating the DAC's performance to assess its linearity and resolution. The reviewing agent 118 evaluates these simulation results, identifying discrepancies or areas for improvement.

Based on the feedback, the coding and tooling agent 112 is executed again to refine the schematic, adjusting component values or configurations to enhance performance. The circuit simulation agent 114 is executed a second time to simulate the updated design, verifying improvements in linearity and resolution. This iterative cycle may repeat several times, with the reviewing agent providing continuous feedback until the design meets all specified requirements.

Finally, the bench agent 116 may be executed to conduct real-world measurements, ensuring the DAC performs as expected under actual operating conditions. This iterative approach, involving multiple executions of the coding and tooling agent and the circuit simulation agent, allows for thorough refinement and optimization, ensuring the final design aligns with the user's objectives and technical specifications.

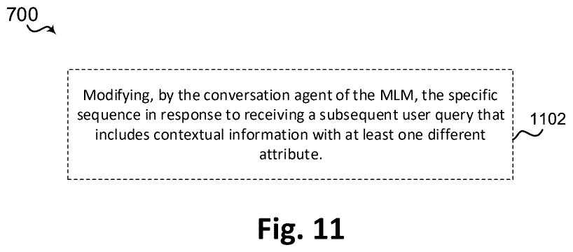

Referring to FIG. 11, in an alternative or additional aspect, at block 1102, the method 700 may further include modifying, by the conversation agent of the MLM, the specific sequence in response to receiving a subsequent user query that includes contextual information with at least one different attribute. For example, in an aspect, computing device 600, one or more processors 605, one or more memories 610, design and analysis component 615, and/or modifying component 650 may be configured to or may comprise means for modifying, by the conversation agent of the MLM, the specific sequence in response to receiving a subsequent user query that includes contextual information with at least one different attribute.

For example, the modifying at block 1102 may include analyzing the subsequent user query to identify new contextual information and attributes that differ from the original query. The conversation agent 108 processes this input using natural language processing algorithms to extract and understand the new requirements or changes in the task context. This analysis involves comparing the attributes of the subsequent query with those of the initial query to determine the differences and their implications for the task execution sequence.

The conversation agent 108 then applies a dynamic sequencing algorithm, which could involve decision-making models or adaptive learning techniques, to adjust the sequence of agent execution accordingly. This algorithm evaluates the impact of the new attributes on the task requirements and identifies which agents need to be re-engaged or newly engaged to address the updated context.

The output of this process is a revised sequence of agents, tailored to incorporate the new contextual information and ensure that the task execution aligns with the updated user query. For instance, if the subsequent query introduces a new performance criterion or design constraint, the conversation agent may modify the sequence to include additional simulations or design iterations, ensuring that the final output meets the revised objectives. This adaptive approach allows the conversation agent to respond flexibly to changes in user requirements, optimizing the task execution process in real-time.

In some aspects, the two or more agents concurrently generate intermediate results before the response to the user query is generated in accordance with the specific sequence. In other words, it is not necessary for a first agent to generate a first intermediate result for the conversation agent followed by a second agent that generates a second intermediate result. Instead, both the first agent and the second agent may work on generating their respective intermediate results in parallel as indicated by the specific sequence.

In some aspects, computing device 600, one or more processors 605, one or more memories 610, design and analysis component 615, and/or selecting component 630 may be configured to or may comprise means for modifying, during generation of the response to the user query, the specific sequence based on an intermediate result generated by one of the two or more agents. In some aspects, this modifying is performed without additional user input. In some aspects, the modifying is performed in response to determining that the specific sequence yields incorrect intermediate results.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. An apparatus for automated analog electronic system design and analysis, comprising:
one or more memories; and
one or more processors coupled with one or more memories and configured, individually or in combination, to:
receive a user query via a user interface, wherein the user query includes at least one attribute indicative of a task in design of electronics, simulation of electronics, and/or analysis of electronics;
identify, by a conversation agent of a machine learning model (MLM), the at least one attribute of the user query;
select from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics;
prompt, by the conversation agent of the MLM, the two or more agents in the specific sequence to collectively generate the response; and
output, by the conversation agent of the MLM, the response via the user interface.

2. The apparatus of claim 1, wherein the plurality of agents include one or more of:
a knowledge retrieval agent that collects information from databases;
a coding agent that writes code in one or more programming languages;
a circuit simulation agent that designs and simulates circuits;
a bench agent that interfaces with instruments to perform the analysis of electronics; and
a reviewing agent that evaluates responses of all other agents in the plurality of agents and identifies errors.

3. The apparatus of claim 1, wherein the one or more processors are further configured to:
determine, by the conversation agent of the MLM or at least one other agent of the MLM, the specific sequence and the two or more agents based on both characteristics of the plurality of agents and historical workflows used to respond to user queries with matching attributes.

4. The apparatus of claim 1, wherein the one or more processors are further configured to:
prompt, by the conversation agent of the MLM, a reviewing agent to evaluate a first response of a first agent from the two or more agents; and
prompt, by the conversation agent of the MLM, the first agent to generate a second response with a modification in response to the reviewing agent indicating that the first response does not meet a requirement of the user query.

5. The apparatus of claim 4, wherein each respective agent of the plurality of agents has a corresponding reviewing agent configured to evaluate intermediate responses generated by the respective agent.

6. The apparatus of claim 1, wherein the two or more agents includes a first agent and a second agent, wherein the first agent is executed after the second agent in the specific sequence, and wherein an intermediate response of the second agent is provided to the first agent to generate the response outputted on the user interface.

7. The apparatus of claim 6, wherein the one or more processors are further configured to:
prompt, by the conversation agent of the MLM, a reviewing agent to evaluate the response of the first agent; and
prompt, by the conversation agent of the MLM, the second agent of the two or more agents to generate a new intermediate response based on a requirement of the user query in response to the reviewing agent indicating that the response does not meet the requirement of the user query.

8. The apparatus of claim 1, wherein the specific sequence comprises executing at least one of the two or more agents multiple times in different parts of the specific sequence.

9. The apparatus of claim 1, wherein the one or more processors are further configured to:
modify, by the conversation agent of the MLM, the specific sequence in response to receive a subsequent user query that includes contextual information with at least one different attribute.

10. The apparatus of claim 1, wherein the MLM is a large language model.

11. The apparatus of claim 1, wherein the two or more agents concurrently generate intermediate results before the response to the user query is generated in accordance with the specific sequence.

12. The apparatus of claim 1, wherein the one or more processors are further configured to:
modify, during generation of the response to the user query, the specific sequence based on an intermediate result generated by one of the two or more agents.

13. The apparatus of claim 12, wherein the modifying is performed without additional user input.

14. The apparatus of claim 12, wherein the modifying is performed in response to determining that the specific sequence yields incorrect intermediate results.

15. A method for automated analog electronic system design and analysis, comprising:
receiving a user query via a user interface, wherein the user query includes at least one attribute indicative of a task in design of electronics, simulation of electronics, and/or analysis of electronics;
identifying, by a conversation agent of a machine learning model (MLM), the at least one attribute of the user query;
selecting from a plurality of agents, by the conversation agent of the MLM, two or more agents that can collectively generate a response to the user query when executed in a specific sequence based on the at least one attribute of the user query, wherein each respective agent of the plurality of agents specializes in a different task in the design of electronics, the simulation of electronics, and/or the analysis of electronics;
prompting, by the conversation agent of the MLM, the two or more agents in the specific sequence to collectively generate the response; and
outputting, by the conversation agent of the MLM, the response via the user interface.

16. The method of claim 15, wherein the plurality of agents include one or more of:
a knowledge retrieval agent that collects information from databases;
a coding agent that writes code in one or more programming languages;
a circuit simulation agent that designs and simulates circuits;
a bench agent that interfaces with instruments to perform the analysis of electronics; and
a reviewing agent that evaluates responses of all other agents in the plurality of agents and identifies errors.

17. The method of claim 15, further comprising:
determining, by the conversation agent of the MLM or at least one other agent of the MLM, the specific sequence and the two or more agents based on both characteristics of the plurality of agents and historical workflows used to respond to user queries with matching attributes.

18. The method of claim 15, further comprising:
prompting, by the conversation agent of the MLM, a reviewing agent to evaluate a first response of a first agent from the two or more agents; and
prompting, by the conversation agent of the MLM, the first agent to generate a second response with a modification in response to the reviewing agent indicating that the first response does not meet a requirement of the user query.

19. The method of claim 18, wherein each respective agent of the plurality of agents has a corresponding reviewing agent configured to evaluate intermediate responses generated by the respective agent.

20. The method of claim 15, wherein the two or more agents includes a first agent and a second agent, wherein the first agent is executed after the second agent in the specific sequence, and wherein an intermediate response of the second agent is provided to the first agent to generate the response outputted on the user interface.
